(19) United States
(12) Patent Application Publication
(10) Pub. No.: US 2025/0254955 A1
(43) Pub. Date: Aug. 7, 2025

(54) MEMORY ARCHITECTURES WITH REPLACEMENT GATE THROUGH PIERS

(71) Applicant: Micron Technology, Inc., Boise, ID (US)

(72) Inventors: Lorenzo Fratin, Buccinasco (MI) (IT); Fabio Pellizzer, Boise, ID (US); Rajasekhar Venigalla, Boise, ID (US); Enrico Varesi, Milano (MI) (IT); Matthew Thorum, Boise, ID (US); Stephen W. Russell, Boise, ID (US); Nirav Vora, Meridian, ID (US)

(21) Appl. No.: 18/787,443

(22) Filed: Jul. 29, 2024

Related U.S. Application Data
(60) Provisional application No. 63/548,699, filed on Feb. 1, 2024.

(51) Int. Cl. H01L 29/66; H01L 21/768; H10B 63/10; H10N 70/00

(52) U.S. Cl. CPC H10D 64/017; H01L 21/76831; H10B 63/10; H10N 70/021; H10N 70/826

(57) ABSTRACT

Methods, systems, and devices for memory architectures with replacement gate through piers are described. A memory architecture with relatively uniform memory cell thickness may be formed by forming a stack of materials including alternating layers of sacrificial material and dielectric material. The processing steps may include forming piers and forming cavities for pillars through the stack of materials. The pillars and electrodes may be formed within the cavities, and a subset of the piers may be removed. The layers of sacrificial material may be removed. A protective liner may be deposited around the electrodes and the remaining piers before depositing layers of metal in place of the sacrificial material. The cavities exposed by removing the subset of piers may be filled with new piers. The remaining piers are removed, and memory cells may be formed between the pillars and the electrodes. Then the removed piers are replaced.

### CROSS REFERENCE

The present application for patent claims priority to U.S. Patent Application No. 63/548,699 by Fratin et al., entitled “MEMORY ARCHITECTURES WITH REPLACEMENT GATE THROUGH PIERS,” filed Feb. 1, 2024, which is assigned to the assignee hereof, and which is expressly incorporated by reference in its entirety herein.

### TECHNICAL FIELD

The following relates to one or more systems for memory, including memory architectures with replacement gate through piers.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a memory array that supports memory architectures with replacement gate through piers in accordance with examples as disclosed herein.

FIGS. 2A, 2B, and 2C show various views of an example of a memory array that supports memory architectures with replacement gate through piers in accordance with examples as disclosed herein.

FIG. 3 shows an example of a memory architecture that supports memory architectures with replacement gate through piers in accordance with examples as disclosed herein.

FIGS. 4A, 4B, 4C, 4D, 4E, 4F, 4G, 4H, 4I, 4J, 4K, 4L, and 4M show examples of processing steps that support memory architectures with replacement gate through piers in accordance with examples as disclosed herein.

FIGS. 5 and 6 show flowcharts illustrating a method or methods that support memory architectures with replacement gate through piers in accordance with examples as disclosed herein.

### DETAILED DESCRIPTION

In some semiconductor manufacturing processes, memory cells may be formed within a memory architecture based on performing a series of processing steps. For example, after a stack of materials including alternating layers of nitride and oxide are formed, piers may be formed through the stack of materials to provide mechanical support for subsequent processing steps. In some alternative processes, trenches may be formed in the stack of materials and then the piers may be formed. Next, cavities for pillars may be formed through the stack of materials (or cavities may be formed through the material included in the trenches), and the layers of nitride may be replaced (e.g., metalized) with a metal to form access lines (e.g., word lines). Then, electrodes may be formed in the cavities and etched back to provide space for the pillars and the memory cells. The pillars may be formed within the cavities and the memory cells may be formed between the pillars and the electrodes. However, performing said processing steps may cause high variability in a thickness of the memory cells. For example, metalizing the layers of nitride may include etching the layers of nitride, depositing layers of metal in voids formed by the etching, and reforming the cavities for the pillars, each of which may be associated with relatively high variability in the resulting structures. Likewise, etching back the electrodes to provide space for the pillars may also result in relatively high variability in the resulting structures. High variability in the resulting structures of said processing steps may cause high variability of the electrical properties of the memory cells across the memory architecture. Specifically, the thickness of the resulting memory cells may vary, which may cause the electrical responses of the memory cells to vary, thereby negatively impacting system performance.

In accordance with examples as described herein, a memory architecture with relatively consistent memory cell thickness may be formed with a series of processing steps. For example, after a stack of materials including alternating layers of nitride and oxide are formed, piers and cavities for pillars may be formed through the stack of materials (e.g., either through a pier-and-pillar process or a trench-and-pier process). Next, pillars and electrodes may be formed within the cavities, and a subset of the piers (e.g., alternating piers) may be removed. Then, the layers of nitride may be etched for metallization, and a protective liner may be deposited around the electrodes and remaining piers before depositing layers of metal in place of the nitride. After performing metallization, the subset of piers is replaced, and the remaining piers are removed to allow for memory cell material placement. The memory cells may be formed between the pillars and the electrodes, then the removed piers are replaced. Performing said processing steps for forming the memory architecture may result in relatively low variability in memory cell thickness. Likewise, materials selected for use in the process steps, as described herein, may have relatively high compatibility with the operations of said processing steps. Forming the memory architecture using said processing steps may not adversely affect operations of the memory cells or otherwise impact system performance.

In addition to applicability in memory systems as described herein, techniques for memory architectures with replacement gate through piers may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by forming memory cells with relatively uniform thickness, which may improve memory cell operation, thereby improving system performance, among other benefits.

Features of the disclosure are illustrated and described in the context of memory devices and arrays. Features of the disclosure are further illustrated and described in the context of memory architectures, processing steps, and flowcharts.

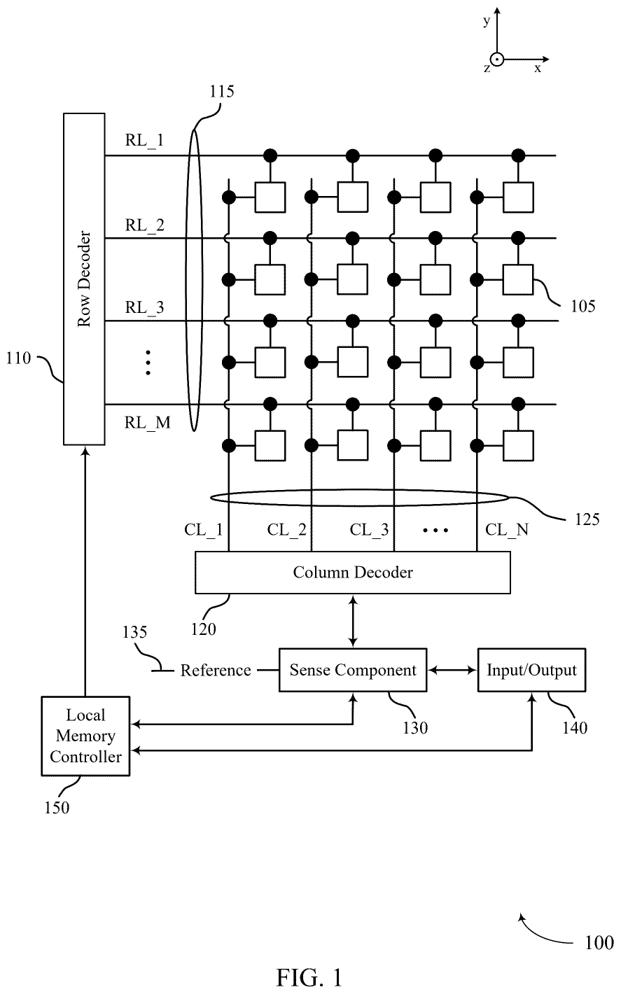

FIG. 1 shows an example of a memory device 100 that supports memory architectures with replacement gate through piers in accordance with examples as disclosed herein. In some examples, the memory device 100 may be referred to as or include a memory die, a memory chip, or an electronic memory apparatus. The memory device 100 may be operable to provide locations to store information (e.g., physical memory addresses) that may be used by a system (e.g., a host device coupled with the memory device 100, for writing information, for reading information).

The memory device 100 may include one or more memory cells 105 that each may be programmable to store different logic states (e.g., a programmed one of a set of two or more possible states). For example, a memory cell 105 may be operable to store one bit of information at a time (e.g., a logic 0 or a logic 1). In some examples, a memory cell 105 (e.g., a multi-level memory cell 105) may be operable to store more than one bit of information at a time (e.g., a logic 00, logic 01, logic 10, a logic 11). In some examples, the memory cells 105 may be arranged in an array.

A memory cell 105 may store a logic state using a configurable material, which may be referred to as a memory element, a storage element, a memory storage element, a material element, a material memory element, a material portion, or a polarity-written material portion, among others. A configurable material of a memory cell 105 may refer to a chalcogenide-based storage component. For example, a chalcogenide storage element may be used in a phase change memory cell, a thresholding memory cell, or a self-selecting memory cell, among other architectures.

In some examples, the material of a memory cell 105 may include a chalcogenide material or other alloy including selenium (Se), tellurium (Te), arsenic (As), antimony (Sb), carbon (C), germanium (Ge), silicon (Si), or indium (In), or various combinations thereof. In some examples, a chalcogenide material having primarily selenium (Se), arsenic (As), and germanium (Ge) may be referred to as a SAG-alloy. In some examples, a SAG-alloy may also include silicon (Si) and such chalcogenide material may be referred to as SiSAG-alloy. In some examples, SAG-alloy may include silicon (Si) or indium (In) or a combination thereof and such chalcogenide materials may be referred to as SiSAG-alloy or InSAG-alloy, respectively, or a combination thereof. In some examples, the chalcogenide material may include additional elements such as hydrogen (H), oxygen (O), nitrogen (N), chlorine (Cl), or fluorine (F), each in atomic or molecular forms.

In some examples, a memory cell 105 may be an example of a phase change memory cell. In such examples, the material used in the memory cell 105 may be based on an alloy (such as the alloys listed above) and may be operated so as to change to different physical state (e.g., undergo a phase change) during normal operation of the memory cell 105. For example, a phase change memory cell 105 may be associated with a relatively disordered atomic configuration (e.g., a relatively amorphous state) and a relatively ordered atomic configuration (e.g., a relatively crystalline state). A relatively disordered atomic configuration may correspond to a first logic state (e.g., a RESET state, a logic 0) and a relatively ordered atomic configuration may correspond to a second logic state (e.g., a logic state different than the first logic state, a SET state, a logic 1).

In some examples (e.g., for thresholding memory cells 105, for self-selecting memory cells 105), some or all of the set of logic states supported by the memory cells 105 may be associated with a relatively disordered atomic configuration of a chalcogenide material (e.g., the material in an amorphous state may be operable to store different logic states). In some examples, the storage element of a memory cell 105 may be an example of a self-selecting storage element. In such examples, the material used in the memory cell 105 may be based on an alloy (e.g., such as the alloys listed above) and may be operated so as to undergo a change to a different physical state during normal operation of the memory cell 105. For example, a self-selecting or thresholding memory cell 105 may have a high threshold voltage state and a low threshold voltage state, where a corresponding “threshold voltage” may refer to a voltage at which or above which the memory cell 105 transitions from a relatively higher-resistance (e.g., non-conductive) state to a relatively lower-resistance (e.g., conductive) state, such as in response to an applied voltage. A high threshold voltage state may correspond to a first logic state (e.g., a RESET state, a logic 0) and a low threshold voltage state may correspond to a second logic state (e.g., a logic state different than the first logic state, a SET state, a logic 1).

During a write operation (e.g., a programming operation) of a self-selecting or thresholding memory cell 105, a polarity used for a write operation may influence (e.g., determine, set, program) a behavior or characteristic of the material of the memory cell 105, such as a thresholding characteristic (e.g., a threshold voltage) of the material. A difference between thresholding characteristics (e.g., resistivity characteristics, conductivity characteristics) of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

The memory device 100 may include access lines (e.g., row lines 115 each extending along an illustrative x-direction, column lines 125 each extending along an illustrative y-direction) arranged in a pattern, such as a grid-like pattern. Access lines may be formed with one or more conductive materials. In some examples, row lines 115, or some portion thereof, may be referred to as word lines. In some examples, column lines 125, or some portion thereof, may be referred to as digit lines or bit lines. References to access lines, or their analogues, are interchangeable without loss of understanding. Memory cells 105 may be positioned at intersections of access lines, such as row lines 115 and the column lines 125. In some examples, memory cells 105 may also be arranged (e.g., addressed) along an illustrative z-direction, such as in an implementation of sets of memory cells 105 being located at different levels (e.g., layers, decks, planes, tiers) along the illustrative z-direction. In some examples, a memory device 100 that includes memory cells 105 at different levels may be supported by a different configuration of access lines, decoders, and other supporting circuitry than shown.

Operations such as read operations and write operations may be performed on the memory cells 105 by activating access lines such as one or more of a row line 115 or a column line 125, among other access lines associated with alternative configurations. For example, by activating a row line 115 and a column line 125 (e.g., applying a voltage to the row line 115 or the column line 125), a memory cell 105 may be accessed in accordance with their intersection. An intersection of a row line 115 and a column line 125, among other access lines, in various two-dimensional or three-dimensional configuration may be referred to as an address of a memory cell 105. In some examples, an access line may be a conductive line coupled with a memory cell 105 and may be used to perform access operations on the memory cell 105. In some examples, the memory device 100 may perform operations responsive to commands, which may be issued by a host device coupled with the memory device 100 or may be generated by the memory device 100 (e.g., by a local memory controller 150).

Accessing the memory cells 105 may be controlled through one or more decoders, such as a row decoder 110 or a column decoder 120, among other examples. For example, a row decoder 110 may receive a row address from the local memory controller 150 and activate a row line 115 based on the received row address. A column decoder 120 may receive a column address from the local memory controller 150 and may activate a column line 125 based on the received column address.

The sense component 130 may be operable to detect a state (e.g., a material state, a resistance state, a threshold state) of a memory cell 105 and determine a logic state of the memory cell 105 based on the detected state. The sense component 130 may include one or more sense amplifiers to convert (e.g., amplify) a signal resulting from accessing the memory cell 105 (e.g., a signal of a column line 125 or other access line). The sense component 130 may compare a signal detected from the memory cell 105 to a reference 135 (e.g., a reference voltage, a reference charge, a reference current). The detected logic state of the memory cell 105 may be provided as an output of the sense component 130 (e.g., to an input/output component 140), and may indicate the detected logic state to another component of the memory device 100 or to a host device coupled with the memory device 100.

The local memory controller 150 may control the accessing of memory cells 105 through the various components (e.g., a row decoder 110, a column decoder 120, a sense component 130, among other components). In some examples, one or more of a row decoder 110, a column decoder 120, and a sense component 130 may be co-located with the local memory controller 150. The local memory controller 150 may be operable to receive information (e.g., commands, data) from one or more different controllers (e.g., an external memory controller associated with a host device, another controller associated with the memory device 100), translate the information into a signaling that can be used by the memory device 100, perform one or more operations on the memory cells 105 and communicate data from the memory device 100 to a host device based on performing the one or more operations. The local memory controller 150 may generate row address signals and column address signals to activate access lines such as a target row line 115 and a target column line 125. The local memory controller 150 also may generate and control various signals (e.g., voltages, currents) used during the operation of the memory device 100. In general, the amplitude, the shape, or the duration of an applied signal discussed herein may be varied and may be different for the various operations discussed in operating the memory device 100.

The local memory controller 150 may be operable to perform one or more access operations on one or more memory cells 105 of the memory device 100. Examples of access operations may include a write operation, a read operation, a refresh operation, a precharge operation, or an activate operation, among others. In some examples, access operations may be performed by or otherwise coordinated by the local memory controller 150 in response to access commands (e.g., from a host device). The local memory controller 150 may be operable to perform other access operations not listed here or other operations related to the operating of the memory device 100 that are not directly related to accessing the memory cells 105.

The memory device 100 may include any quantity of non-transitory computer readable media that support memory architectures with replacement gate through piers. For example, a local memory controller 150, a row decoder 110, a column decoder 120, a sense component 130, or an input/output component 140, or any combination thereof may include or may access one or more non-transitory computer readable media storing instructions (e.g., firmware) for performing the functions ascribed herein to the memory device 100. For example, such instructions, if executed by the memory device 100, may cause the memory device 100 to perform one or more associated functions as described herein.

In accordance with examples as described herein, a memory architecture with relatively consistent memory cell thickness may be formed with a series of processing steps. For example, after a stack of materials including alternating layers of nitride and oxide are formed, piers and cavities for pillars may be formed through the stack of materials. Next, pillars and electrodes may be formed within the cavities, and a subset of the piers (e.g., alternating piers) may be removed. Then, the layers of nitride may be etched for metallization, and a protective liner may be deposited around the electrodes and remaining piers before depositing layers of metal in place of the nitride. After performing metallization, the piers of the subset of piers are replaced and the remaining piers are removed to allow for memory cell material placement. The memory cells 105 may be formed between the pillars and the electrodes, then the removed piers are replaced. Performing said processing steps for forming the memory architecture may result in relatively low variability in memory cell thickness. Likewise, materials selected for use in the process steps, as described herein, may have relatively high compatibility with the operations of said processing steps. Forming the memory architecture using said processing steps may not adversely affect operations of the memory cells 105 or otherwise impact system performance.

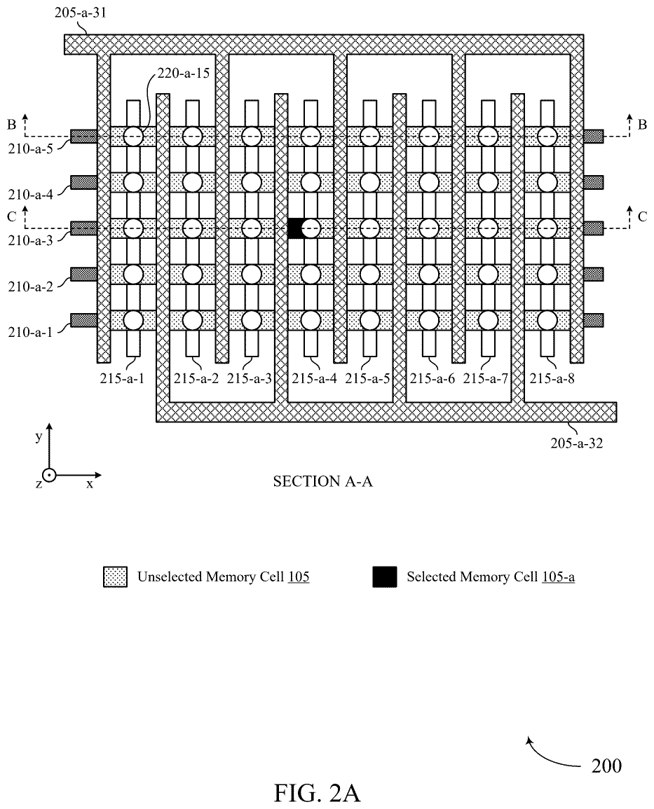

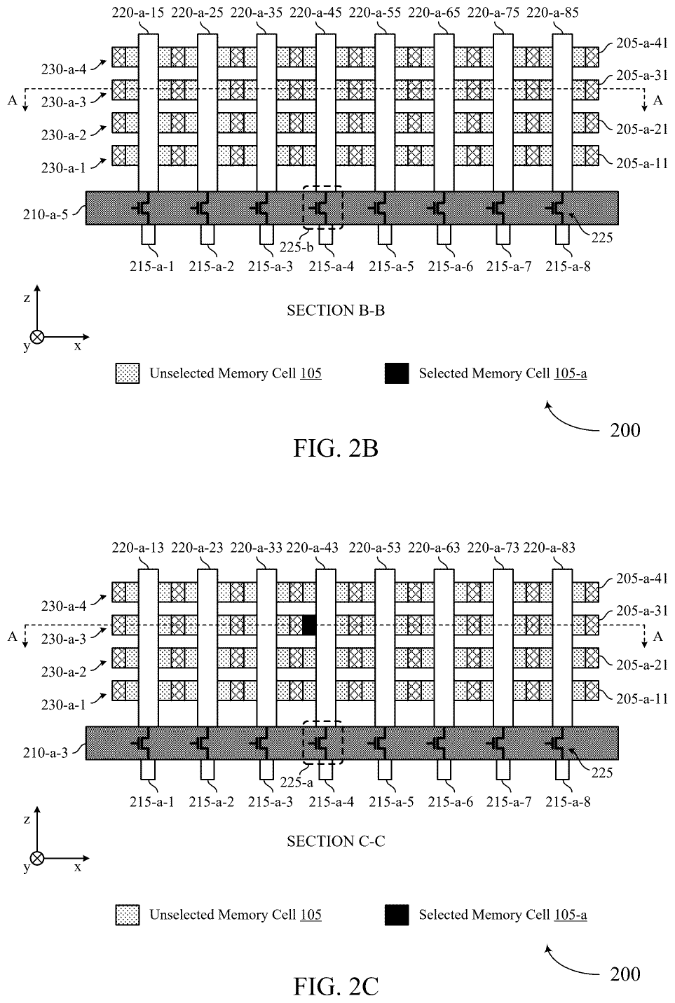

FIGS. 2A, 2B, and 2C show an example of a memory array 200 that supports memory architectures with replacement gate through piers in accordance with examples as disclosed herein. The memory array 200 may be included in a memory device 100, and illustrates an example of a three-dimensional arrangement of memory cells 105 that may be accessed by various conductive structures (e.g., access lines). FIG. 2A illustrates a top section view (e.g., SECTION A-A) of the memory array 200 relative to a cut plane A-A as shown in FIGS. 2B and 2C. FIG. 2B illustrates a side section view (e.g., SECTION B-B) of the memory array 200 relative to a cut plane B-B as shown in FIG. 2A. FIG. 2C illustrates a side section view (e.g., SECTION C-C) of the memory array 200 relative to a cut plane C-C as shown in FIG. 2A. The section views may be examples of cross-sectional views of the memory array 200 with some aspects (e.g., dielectric structures) removed for clarity. Elements of the memory array 200 may be described relative to an x-direction, a y-direction, and a z-direction, as illustrated in each of FIGS. 2A, 2B, and 2C. Although some elements included in FIGS. 2A, 2B, and 2C are labeled with a numeric indicator, other corresponding elements are not labeled, although they are the same or would be understood to be similar, in an effort to increase visibility and clarity of the depicted features. Further, although some quantities of repeated elements are shown in the illustrative example of memory array 200, techniques in accordance with examples as described herein may be applicable to any quantity of such elements, or ratios of quantities between one repeated element and another.

In the example of memory array 200, memory cells 105 and word lines 205 may be distributed along the z-direction according to levels 230 (e.g., decks, layers, planes, tiers, as illustrated in FIGS. 2B and 2C). In some examples, the z-direction may be orthogonal to a substrate (not shown) of the memory array 200, which may be below the illustrated structures along the z-direction. Although the illustrative example of memory array 200 includes four levels 230, a memory array 200 in accordance with examples as disclosed herein may include any quantity of one or more levels 230 (e.g., 64 levels, 128 levels) along the z-direction.

Each word line 205 may be an example of a portion of an access line that is formed by one or more conductive materials (e.g., one or more metal portions, one or more metal alloy portions). As illustrated, a word line 205 may be formed in a comb structure, including portions (e.g., projections, tines) extending along the y-direction through gaps (e.g., alternating gaps) between pillars 220. For example, as illustrated, the memory array 200, may include two word lines 205 per level 230 (e.g., according to odd word lines 205-a-n1 and even word lines 205-a-n2 for a given level, n), where such word lines 205 of the same level 230 may be described as being interleaved (e.g., with portions of an odd word line 205-a-n1 projecting along the y-direction between portions of an even word line 205-a-n2, and vice versa). In some examples, an odd word line 205 (e.g., of a level 230) may be associated with a first memory cell 105 on a first side (e.g., along the x-direction) of a given pillar 220 and an even word line (e.g., of the same level 230) may be associated with a second memory cell 105 on a second side (e.g., along the x-direction, opposite the first memory cell 105) of the given pillar 220. Thus, in some examples, memory cells 105 of a given level 230 may be addressed (e.g., selected, activated) in accordance with an even word line 205 or an odd word line 205.

Each pillar 220 may be an example of a portion of an access line (e.g., a conductive pillar portion) that is formed by one or more conductive materials (e.g., one or more metal portions, one or more metal alloy portions). As illustrated, the pillars 220 may be arranged in a two-dimensional array (e.g., in an xy-plane) having a first quantity of pillars 220 along a first direction (e.g., eight pillars along the x-direction, eight rows of pillars), and having a second quantity of pillars 220 along a second direction (e.g., five pillars along the y-direction, five columns of pillars). Although the illustrative example of memory array 200 includes a two-dimensional arrangement of eight pillars 220 along the x-direction and five pillars 220 along the y-direction, a memory array 200 in accordance with examples as disclosed herein may include any quantity of pillars 220 along the x-direction and any quantity of pillars 220 along the y-direction. Further, as illustrated, each pillar 220 may be coupled with a respective set of memory cells 105 (e.g., along the z-direction, one or more memory cells 105 for each level 230). A pillar 220 may have a cross-sectional area in an xy-plane that extends along the z-direction. Although illustrated with a circular cross-sectional area in the xy-plane, a pillar 220 may be formed with a different shape, such as having an elliptical, square, rectangular, polygonal, or other cross-sectional area in an xy-plane.

The memory cells 105 each may include a chalcogenide material. In some examples, the memory cells 105 may be examples of thresholding memory cells. Each memory cell 105 may be accessed (e.g., addressed, selected) according to an intersection between a word line 205 (e.g., a level selection, which may include an even or odd selection within a level 230) and a pillar 220. For example, as illustrated, a selected memory cell 105-a of the level 230-a-3 may be accessed according to an intersection between the pillar 220-a-43 and the word line 205-a-32.

A memory cell 105 may be accessed (e.g., written to, read from) by applying an access bias (e.g., an access voltage, V_{access}, which may be a positive voltage or a negative voltage) across the memory cell 105. In some examples, an access bias may be applied by biasing a selected word line 205 with a first voltage (e.g., V_{access}/2) and by biasing a selected pillar 220 with a second voltage (e.g., −V_{access}/2), which may have an opposite sign relative to the first voltage. Regarding the selected memory cell 105-a, a corresponding access bias (e.g., the first voltage) may be applied to the word line 205-a-32, while other unselected word lines 205 may be grounded (e.g., biased to 0V). In some examples, a word line bias may be provided by a word line driver (not shown) coupled with one or more of the word lines 205.

To apply a corresponding access bias (e.g., the second voltage) to a pillar 220, the pillars 220 may be configured to be selectively coupled with a sense line 215 (e.g., a digit line, a column line, an access line extending along the y-direction) via a respective transistor 225 coupled between (e.g., physically, electrically) the pillar 220 and the sense line 215. In some examples, the transistors 225 may be vertical transistors (e.g., transistors having a channel along the z-direction, transistors having a semiconductor junction along the z-direction), which may be formed above the substrate of the memory array 200 using various techniques (e.g., thin film techniques). In some examples, a selected pillar 220, a selected sense line 215, or a combination thereof may be an example of a selected column line 125 described with reference to FIG. 1 (e.g., a bit line).

The transistors 225 (e.g., a channel portion of the transistors 225) may be activated by gate lines 210 (e.g., activation lines, selection lines, a row line, an access line extending along the x-direction) coupled with respective gates of a set of the transistors 225 (e.g., a set along the x-direction). In other words, each of the pillars 220 may have a first end (e.g., towards the negative z-direction, a bottom end) configured for coupling with an access line (e.g., a sense line 215). In some examples, the gate lines 210, the transistors 225, or both may be considered to be components of a row decoder 110 (e.g., as pillar decoder components). In some examples, the selection of (e.g., biasing of) pillars 220, or sense lines 215, or various combinations thereof, may be supported by a column decoder 120, or a sense component 130, or both.

To apply the corresponding access bias (e.g., −V_{access}/2) to the pillar 220-a-43, the sense line 215-a-4 may be biased with the access bias, and the gate line 210-a-3 may be grounded (e.g., biased to 0V) or otherwise biased with an activation voltage. In an example where the transistors 225 are n-type transistors, the gate line 210-a-3 being biased with a voltage that is relatively higher than the sense line 215-a-4 may activate the transistor 225-a (e.g., cause the transistor 225-a to operate in a conducting state), thereby coupling the pillar 220-a-43 with the sense line 215-a-4 and biasing the pillar 220-a-43 with the associated access bias. However, the transistors 225 may include different channel types, or may be operated in accordance with different biasing schemes, to support various access operations.

In some examples, unselected pillars 220 of the memory array 200 may be electrically floating when the transistor 225-a is activated, or may be coupled with another voltage source (e.g., grounded, via a high-resistance path, via a leakage path) to avoid a voltage drift of the pillars 220. For example, a ground voltage being applied to the gate line 210-a-3 may not activate other transistors coupled with the gate line 210-a-3, because the ground voltage of the gate line 210-a-3 may not be greater than the voltage of the other sense lines 215 (e.g., which may be biased with a ground voltage or may be floating). Further, other unselected gate lines 210, including gate line 210-a-5 as shown in FIG. 2B, may be biased with a voltage equal to or similar to an access bias (e.g., −V_{access}/2, or some other negative bias or bias relatively near the access bias voltage), such that transistors 225 along an unselected gate line 210 are not activated. Thus, the transistor 225-b coupled with the gate line 210-a-5 may be deactivated (e.g., operating in a non-conductive state), thereby isolating the voltage of the sense line 215-a-4 from the pillar 220-a-45, among other pillars 220.

In a write operation, a memory cell 105 may be written to by applying a write bias (e.g., where V_{access}=V_{write}, which may be a positive voltage or a negative voltage) across the memory cell 105. In some examples, a polarity of a write bias may influence (e.g., determine, set, program) a behavior or characteristic of the material of the memory cell 105, such as the threshold voltage of the material. For example, applying a write bias with a first polarity may set the material of the memory cell 105 with a first threshold voltage, which may be associated with storing a logic 0. Further, applying a write bias with a second polarity (e.g., opposite the first polarity) may set the material of the memory cell with a second threshold voltage, which may be associated with storing a logic 1. A difference between threshold voltages of the material of the memory cell 105 for different logic states stored by the material of the memory cell 105 (e.g., a difference between threshold voltages when the material is storing a logic state ‘0’ versus a logic state ‘1’) may correspond to the read window of the memory cell 105.

In a read operation, a memory cell 105 may be read from by applying a read bias (e.g., where V_{access}=V_{read}, which may be a positive voltage or a negative voltage) across the memory cell 105. In some examples, a logic state of the memory cell 105 may be evaluated based on whether the memory cell 105 thresholds (e.g., transitions to a relatively lower-resistance or conductive state, permits current) in the presence of the applied read bias. For example, such a read bias may cause a memory cell 105 storing a first logic state (e.g., a logic 0) to threshold (e.g., permit a current flow, permit a current above a threshold current), and may not cause a memory cell 105 storing a second logic state (e.g., a logic 1) to threshold (e.g., may not permit a current flow, may permit a current below a threshold current).

In accordance with examples as described herein, a memory architecture with relatively consistent memory cell thickness may be formed with a series of processing steps. For example, after a stack of materials including alternating layers of nitride and oxide are formed, piers and cavities for pillars may be formed through the stack of materials. Next, pillars and electrodes may be formed within the cavities, and a subset of the piers (e.g., alternating piers) may be removed. Then, the layers of nitride may be etched for metallization, and a protective liner may be deposited around the electrodes and remaining piers before depositing layers of metal in place of the nitride. After performing metallization, the piers of the subset of piers are replaced and the remaining piers are removed to allow for memory cell material placement. The memory cells 105 may be formed between the pillars and the electrodes, then the removed piers are replaced. Performing said processing steps for forming the memory architecture may result in relatively low variability in memory cell thickness. Likewise, materials selected for use in the process steps, as described herein, may have relatively high compatibility with the operations of said processing steps. Forming the memory architecture using said processing steps may not adversely affect operations of the memory cells 105 or otherwise impact system performance.

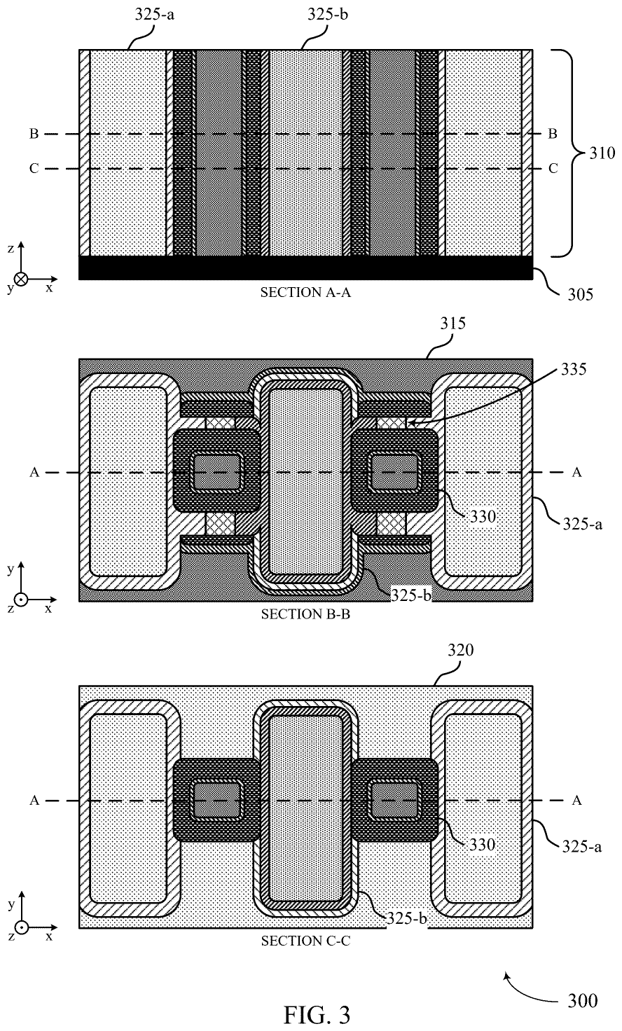

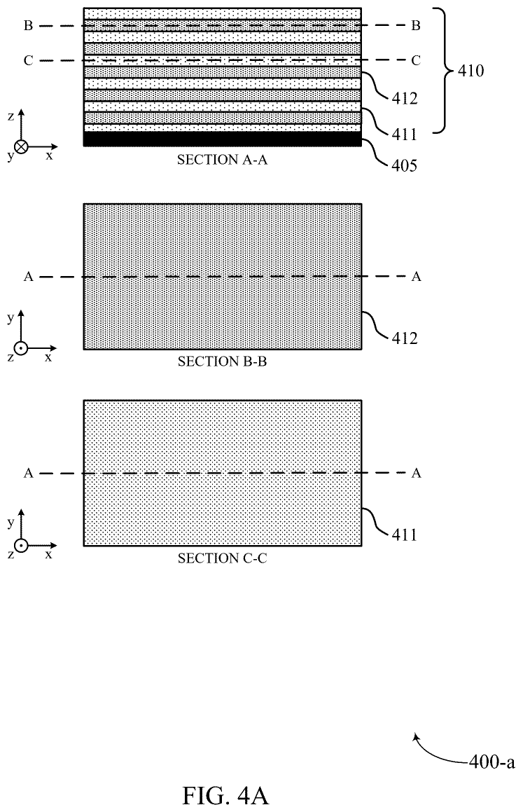

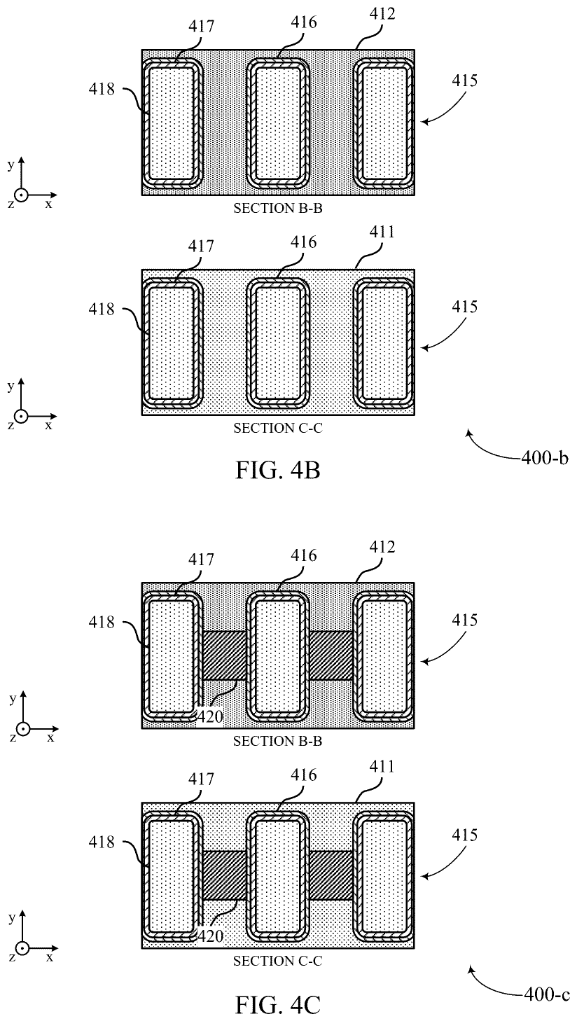

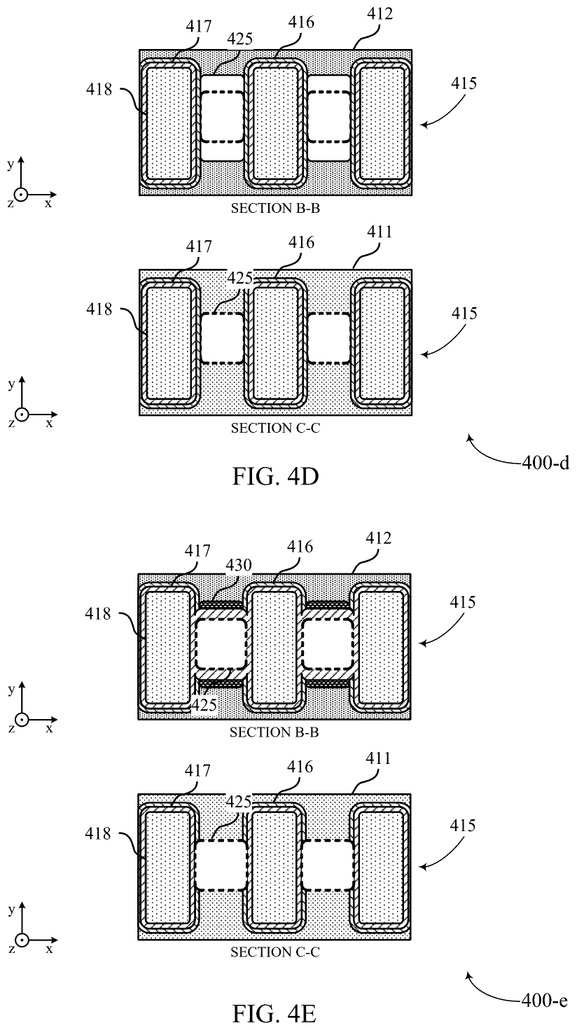

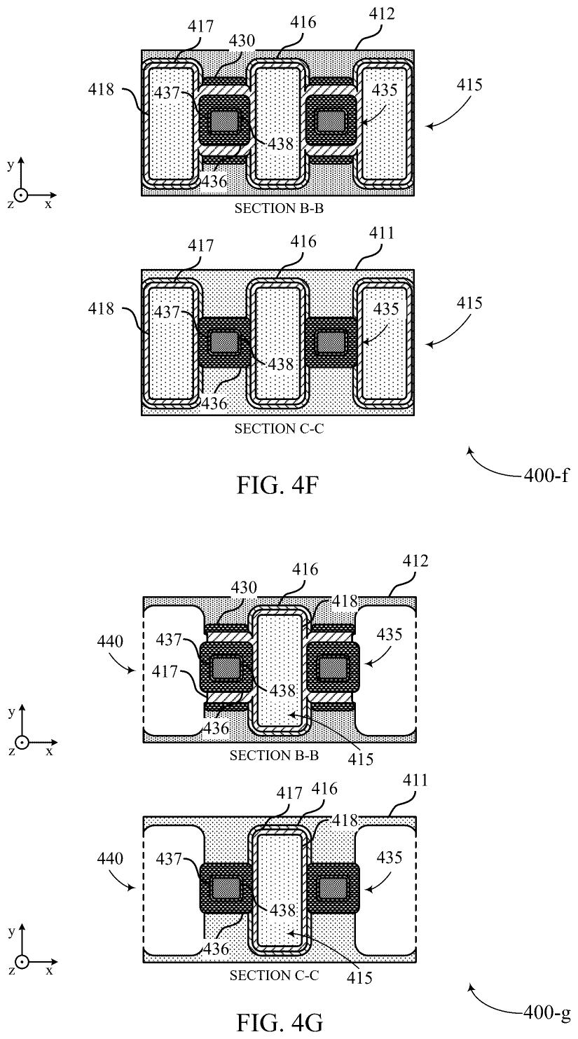

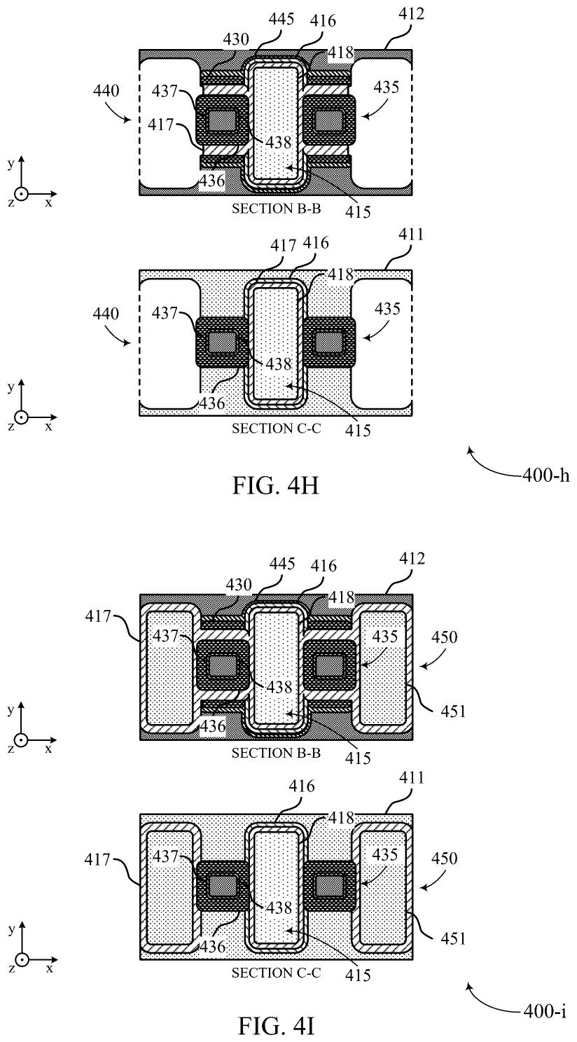

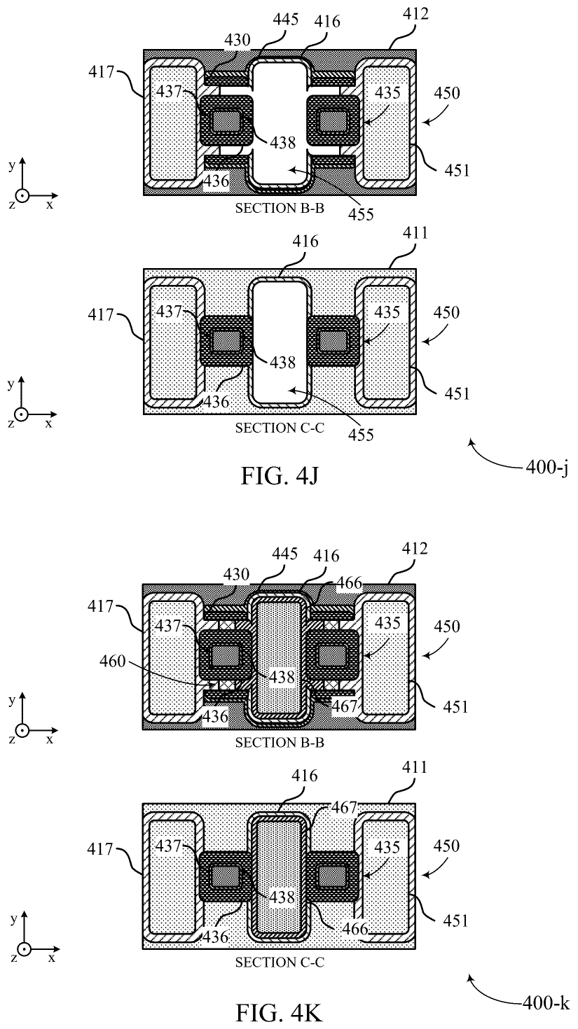

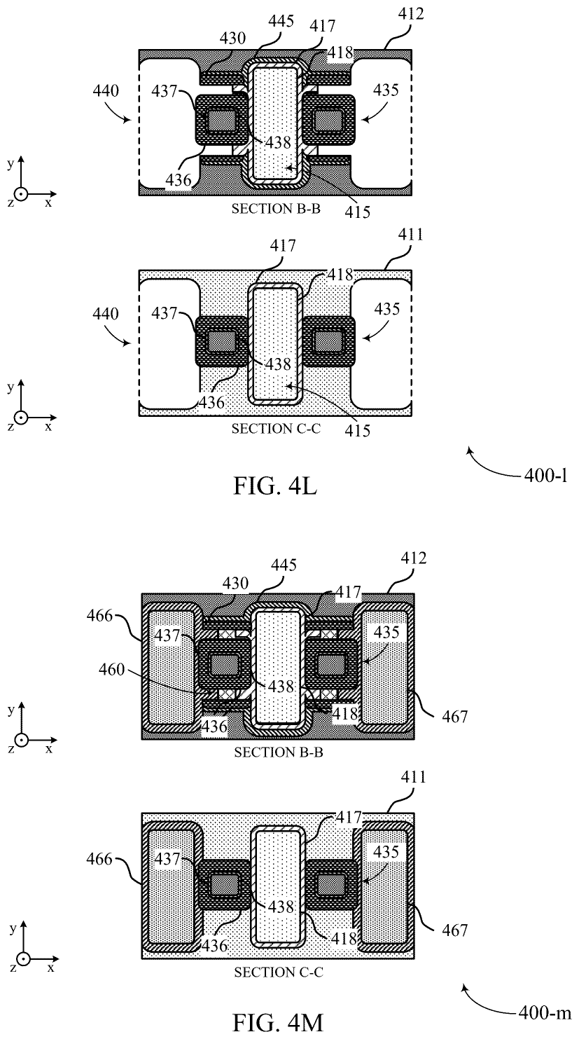

FIG. 3 shows an example of a memory architecture 300 that supports memory architectures with replacement gate through piers in accordance with examples as disclosed herein. The memory architecture 300 may implement aspects of, or be implemented by, a memory device, which may be an example of a memory device 100, as described with reference to FIG. 1. For example, the memory architecture may include memory cells 335, which may be examples of memory cells 105. For illustrative purposes, aspects of the memory architecture 300 may be described with reference to an x-direction, a y-direction, and a z-direction of the illustrated coordinate systems. For example, FIG. 3 illustrates the memory architecture 300 from various cross-sectional views: Section A-A illustrates the memory architecture 300 in an xz-plane cut at section line A-A; Section B-B illustrates the memory architecture 300 in an xy-plane cut at section line B-B; and Section C-C illustrates the memory architecture 300 in an xy-plane cut at section line C-C and offset from the xy-plane associated with Section B-B. The memory architecture 300 illustrates the memory array resulting from the processing steps 400, as described with reference to FIG. 4.

The memory architecture 300 may include a substrate 305, which may be a semiconductor material (e.g., surface) in an xy-plane upon which other components may be formed. The memory architecture 300 may include a stack of materials 310 formed above the substrate 305 along the z-direction. The stack of materials 310 may include alternating layers 315 and 320, where layers 315 may be a metal material and layers 320 may be a dielectric material. For example, layers 315 may be a tungsten material and layers 320 may be an oxide material, among other options. In some cases, the layers 315 may form interleaving word line structures for accessing the memory cells 335 of the memory architecture 300.

The memory architecture 300 may include piers 325 configured to provide mechanical support for other components or structures of the memory architecture 300. In some cases, the piers 325 may be implemented to facilitate performing processing steps for forming the memory architecture 300. For example, the piers 325 may be selectively removed to enable performing operations for forming structures within the stack of materials 310. In some cases, the piers 325 may include a subset of piers 325-a and another subset of piers 325-b. The subset of piers 325-a and the subset of piers 325-b may be formed using different materials and may be removed and replaced at different times during forming the memory architecture 300. In some examples, the subset of piers 325-a may include alternating piers 325 and the subset of piers 325-b may include other alternating piers 325, such that the subset of piers 325-a may alternate with the subset of piers 325-b (e.g., 325-a, 325-b, 325-a, 325-b).

The memory architecture 300 may include pillars 330 configured to facilitate accessing the memory cells 335. For example, the pillars 330 may be conductive channels that may be supplied with voltages to activate the respective memory cells 335 associated with the respective pillars 330. In some cases, the pillars 330 may be formed between each pier 325. The memory architecture 300 may include the memory cells 335, which may be formed at each of the layers 315. Each memory cell 335 may be coupled with a respective pillar 330 and a respective word line associated with the corresponding layer 315. Each memory cell 335 may be configured to store one or more bits of information and may be access based on activating the respective pillar 330 and the respective word line.

The memory architecture 300 may be formed such that a thickness of each memory cell 335 may be relatively uniform throughout the memory architecture 300. That is, the processing steps and materials used for forming the memory architecture 300 may support consistency when forming the memory cells 335. Uniform memory cell thickness may be associated with consistency for operating the memory cells 335 throughout the memory architecture 300, which may improve system performance, among other benefits.

FIGS. 4A, 4B, 4C, 4D, 4E, 4F, 4G, 4H, 4I, 4J, 4K, 4L, and 4M show examples of processing steps 400 (e.g., processing step 400-a, processing step 400-b, processing step 400-c, processing step 400-d, processing step 400-e, processing step 400-f, processing step 400-g, processing step 400-h, processing step 400-i, processing step 400-j, processing step 400-k, processing step 400-1, processing step 400-m) that support memory architectures with replacement gate through piers in accordance with examples as disclosed herein. The processing steps 400 may illustrate aspects of manufacturing operations for fabricating aspects of a memory architecture, which may be an example of a memory architecture 300, as described with reference to FIG. 3, or implemented by a memory device 100, as described with reference to FIG. 1. For example, performing the processing steps 400 as described herein may result in the memory architecture 300.

For illustrative purposes, aspects of the memory architecture may be described with reference to an x-direction, a y-direction, and a z-direction of the illustrated coordinate system. In some cases, the memory architecture may be described relative to various cross-sectional views. For example, processing step 400-a illustrates the memory architecture from various cross-sectional views: Section A-A illustrates the memory architecture in an xz-plane cut at section line A-A; Section B-B illustrates the memory architecture in an xy-plane cut at section line B-B; and Section C-C illustrates the memory architecture in an xy-plane cut at section line C-C and offset from the xy-plane associated with Section B-B. Additionally, proceeding processing steps 400 may show the memory architecture at Section B-B and Section C-C which may be understood as being relative to Section A-A from the processing step 400-a.

Although the processing steps 400 illustrate examples of relative dimensions and quantities of various features, aspects of the memory architecture may be implemented with other relative dimensions or quantities of such features in accordance with examples as disclosed herein. In the following description of the processing steps 400, some methods, techniques, processes, and operations may be performed in different orders or at different times. Further, some operations may be left out of the processing steps 400, or other operations may be added to the processing steps 400. The processing steps 400 may illustrate operations associated with forming memory cells of the memory architecture such that the memory cells may have a relatively uniform thickness throughout the memory architecture.

Operations illustrated in and described with reference to FIGS. 4A through 4M may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by a controller, such as a process controller, or its components as described herein.

FIG. 4A illustrates a first processing step 400-a for forming a stack of materials 410. The processing step 400-a may include forming the stack of materials 410 above a substrate 405 along the z-direction. The stack of materials 410 may include alternating layers 411 and 412, each layer 411 and 412 associated with a respective xy-plane. For example, the processing step 400-a may include depositing layers 411 and 412 in an alternating pattern along the z-direction. In some cases, the layers 411 may include a dielectric material and the layers 412 may include a sacrificial material (e.g., a material associated with being removed at a later processing step 400). For example, the layers 411 may be an oxide material, and the layers 412 may be a nitride material.

FIG. 4B illustrates a second processing step 400-b for forming piers 415 within the stack of materials 410 along the z-direction. In some cases, the piers 415 may include multiple layers of materials, including a liner 416, a liner 417, and a polysilicon 418 (e.g., a polysilicon material). In some examples, the liner 416 may be a silicon carbide material, a silicon oxy-carbide material, or a hafnium silicon oxide material, or a combination thereof, among other options. In some such examples, the liner 417 may be a silicon carbonitride material, among other options. In some implementations, the materials associated with the liner 416 and the liner 417 may be selected based on identifying a compatibility between the materials and the processing steps 400. Although illustrated in FIGS. 4A through 4K as including the liner 416, in some implementations, the piers 415 may not include the liner 416, as shown in FIGS. 4L and 4M. In some such implementations, the piers 415 may include the liner 417 and the polysilicon 418.

The processing step 400-b may include etching the stack of materials 410 to form cavities within the stack of materials 410. Next, the processing step 400-b may include depositing the liner 416 into the cavities to fill the cavities with the material associated with the liner 416. Then, the processing step 400-b may include etching the liner 416 to form cavities within the liner 416. Next, the processing step 400-b may include depositing the liner 417 into the cavities to fill the cavities with the material associated with the liner 417. After depositing the liner 417, the processing step 400-b may include etching the liner 417 to form cavities within the liner 417. Finally, the processing step 400-b may include depositing the polysilicon 418 into the cavities to fill the cavities with the polysilicon 418.

FIG. 4C illustrates a third processing step 400-c for forming a trench 420 through the stack of materials 410. The processing step 400-c is an optional processing step which may be performed prior to the processing step 400-b. The processing step 400-c may include etching a trench 420 through the stack of materials along the z-direction and extending in the x-direction, and depositing a dielectric material within the trench 420 to fill the trench 420. Then, the trench 420 may be used for aligning the piers 415 along the x-direction during forming the piers 415. In some examples, the trench 420 may be formed before the piers 415 are formed.

FIG. 4D illustrates a fourth processing step 400-d for forming cavities 425 through the stack of materials 410. The processing step 400-d may include etching the stack of materials 410 along the z-direction to form the cavities 425. The cavities 425 may be positioned between the piers 415 and may be aligned with the piers 415 along the x-direction. In some cases, the cavities 425 may be formed such that the cavities 425 may have a greater width along the y-direction at the layers 412 than at the layers 411 of the stack of materials 410.

FIG. 4E illustrates a fifth processing step 400-e for forming electrodes 430 within the cavities 425. The processing step 400-e may include depositing an electrode material (e.g., carbon, metal, or another conductive material) within the cavities 425 at the layers 412 of the stack of materials 410. For example, the electrode material may be deposited within the cavities 425 at portions of the cavities 425 associated with the greater width along the y-direction. Then, the processing step 400-e may include etching the electrode material. In some examples, etching the electrode material may include etching an exposed portion of the liner 416 of the adjacent piers 415, such that the portion of the liner 416 contacting the cavities 425 may be removed. After etching the electrode material, the liner 417 may be deposited with the cavities 425 against the electrode material. In some examples, depositing the liner 417 within the cavities 425 may include depositing the liner 417 at the portion of the liner 416 removed during etching the electrode material. In some implementations, the process flow 400 may include depositing a cell placeholder material instead of the liner 417, where the cell placeholder material may be a hafnium oxide material or a silicon nitride material. Finally, the processing step 400-e may include re-etching the cavities 425, however re-etching the cavities 425 may not include forming the cavities 425 with greater widths at the layers 412. Thus, the cavities 425 may have a consistent width along the y-direction throughout the stack of materials 410. In some cases, reforming the cavities 425 may include removing a portion of the liner 417 (e.g., or the cell placeholder material).

FIG. 4F illustrates a sixth processing step 400-f for forming pillars 435 within the cavities 425. In some cases, the pillars 435 may include multiple layers of materials, including an electrode material 436, a barrier material 437 (e.g., a protective liner), and a conductive material 438. In some examples, the electrode material 436 may be a carbon (e.g., or metal) material, the barrier material 437 may be a titanium nitride material, and the conductive material 438 may be a tungsten material, among other options. In some implementations, the materials associated with the barrier material 437 may be selected based on identifying a compatibility between the materials and the processing steps 400. The processing step 400-f may include depositing the electrode material 436 into the cavities 425 to fill the cavities 425 with the electrode material 436. Next, the processing step 400-f may include etching the electrode material 436 to form cavities within the electrode material 436. Then, the processing step 400-f may include depositing the barrier material 437 into the cavities to fill the cavities with the barrier material 437. After depositing the barrier material 437, the processing step 400-f may include etching the barrier material 437 to form cavities within the barrier material 437. Finally, the processing step 400-f may include depositing the conductive material 438 into the cavities to fill the cavities with the conductive material 438.

FIG. 4G illustrates a seventh processing step 400-g for removing a subset of the piers 415. The subset of the piers 415 may include alternating piers along the x-direction. For example, every other pier along the x-direction may be removed during the processing step 400-g. The processing step 400-g may include etching the subset of the piers 415, which may include etching the liner 416, the liner 417, and the polysilicon 418 associated with each of the piers 415 of the subset. Removing the subset of the piers 415 may form cavities 440 in place of the subset of the piers 415.

FIG. 4H illustrates an eighth processing step 400-h for performing metallization, which includes replacing the sacrificial material at the layers 412 with a metal material (e.g., a tungsten material). For example, the processing step 400-h may include removing the nitride material from the layers 412 based on etching the nitride material at each layer 412. Then, the processing step 400-h may include depositing a protective liner 445 at least partially around the piers 415 and the pillars 435. For example, the protective liner 445 may be deposited around the remaining piers 415 (e.g., the piers 415 excluding the subset of the piers 415 removed at the processing step 400-g) and the pillars 435 at the layers 412. In some such examples, the protective liner 445 may be deposited above and below the piers 415 and the pillars 435 along the y-direction, contacting the piers 415 and the pillars 435. In some implementations, the protective liner 445 may be a titanium nitride material or another barrier material. After depositing the protective liner 445, the processing step 400-h may include depositing the metal material at the layers 412 to fill the layers 412 (e.g., to fill voids associated with removing the sacrificial material). In some cases, the metal material may be a tungsten material. For example, the metal material may be the same tungsten material as the conductive material 438. In some cases, the processing step 400-h may be followed by a processing step 400-i (e.g., then processing step 400-j and processing step 400-k). However, in other cases, the processing step 400-h may be followed by a processing step 400-1 (e.g., then processing step 400-m).

FIG. 4I illustrates a ninth processing step 400-i for reforming the subset of the piers 415. The processing step 400-i may include forming second piers 450 in the cavities 440, which may be associated with a same position as the subset of the piers 415. For example, the processing step 400-i may include depositing the liner 417 into the cavities 440 to fill the cavities 440 with the material associated with the liner 417. Then, the processing step 400-i may include etching the liner 417 to form cavities with the liner 417. Finally, the processing step 400-i may include depositing a dielectric material 451 within the cavities to fill the cavities with the dielectric material 451. In some cases, the dielectric material 451 may be an oxide material. For example, the dielectric material 451 may be the same oxide material as the oxide material at the layers 411.

FIG. 4J illustrates a tenth processing step 400-j for removing the piers 415 (e.g., excluding the second piers 350). The processing step 400-i may include etching the piers 415, which may include etching the liner 417 and the polysilicon 418 associated with each of the piers 415. Removing the liner 417 may remove a portion of the liner 416 extending between the electrodes 430 and the pillars 435 at the layers 412. However, the processing step 400-i may not include etching the liner 416 associated with each of the piers 415. Removing the piers 415 may form cavities 455 in place of the piers 415.

FIG. 4K illustrates an eleventh processing step 400-k for forming memory cells 460. The processing step 400-k may include depositing memory cell material in place of the portion of the liner 416 extending between the electrodes 430 and the pillars 435 at the layers 412. Thus, the memory cells 460 may be contacting the electrodes 430 and the pillars 435 at the layers 412. After forming the memory cells 460, the processing step 400-k may include reforming the piers 415. That is, the processing step 400-k may include depositing a liner 466 into the cavities 455 to fill the cavities 455 with the liner 466. In some cases, depositing the liner 466 may include depositing the liner 466 at least partially into the region extending between the electrodes 430 and the pillars 435 at the layers 412. Then, the processing step 400-k may include etching the liner 466 to form cavities within the liner 466. Finally, the processing step 400-k may include depositing a dielectric material 467 into the cavities. In some cases, the liner 466 may be a hafnium-oxide material and the dielectric material 467 may be a nitride material.

FIG. 4L illustrates a twelfth processing step 400-1 for extending the cavities 440. The processing step 400-1 may be performed after the processing step 400-h, in place of the processing steps 400-i through 400-k. The processing step 400-1 may include removing a portion of the liner 417 extending around the pillars 435, such that the cavities 440 formed in place of the subset of the piers 415 may be extended. In some cases, extending the cavities 440 may include extending the cavities 440 adjacent to pillars 435 (e.g., along the y-direction, extending in the x-direction). Using the processing steps 400-1 and 400-m instead of 400-i, 400-j, and 400-k may provide eliminate exhuming both subsets of pillars. In processing steps 400-1 and 400-m the same subset of piers is exhumed, and those cavities are used to perform the metallization process (e.g., the replacement gate process) and used to form the memory cells. In contrast, in the processing steps 400-i, 400-j, and 400-k the cavities left by exhuming the first subset of piers are filled in with material after the metallization process (e.g., the replacement gate process) and a second subset of cavities are exhumed to form the memory cell. In some cases, to perform the processing steps 400-1 and 400-m, the manufacturing process more form word line contacts (e.g., through a staircase structure) before performing the metallization process (e.g., the replacement gate process).

FIG. 4M illustrates a thirteenth processing step 400-m for forming memory cells 460. The processing step 400-m may include depositing memory cell material in the extended portions of the cavities 440 formed in processing step 400-1. That is, the memory cell material may be deposited between the electrodes 430 and the pillars 435 at the layers 412. Thus, the memory cells 460 may be contacting the electrodes 430 and the pillars 435 at the layers 412. After forming the memory cells 460, the processing step 400-m may include reforming the piers 415. That is, the processing step 400-m may include depositing a liner 466 into the cavities 440 to fill the cavities 440 with the liner 466. In some cases, depositing the liner 466 may include depositing the liner 466 at least partially into the region extending between the electrodes 430 and the pillars 435 at the layers 412. Then, the processing step 400-m may include etching the liner 466 to form cavities within the liner 466. Finally, the processing step 400-m may include depositing a dielectric material 467 into the cavities. In some cases, the liner 466 may be a hafnium-oxide material and the dielectric material 467 may be a nitride material.

In some cases, performing the processing steps 400 may create a memory architecture where a thickness of each memory cell 460 of the memory architecture has a relatively uniform thickness throughout the memory architecture. That is, the processing steps 400 and the materials used for forming the memory architecture may support consistency when forming the memory cells 460. Uniform memory cell thickness may be associated with consistency for operating the memory cells 460 throughout the memory architecture, which may improve system performance, among other benefits.

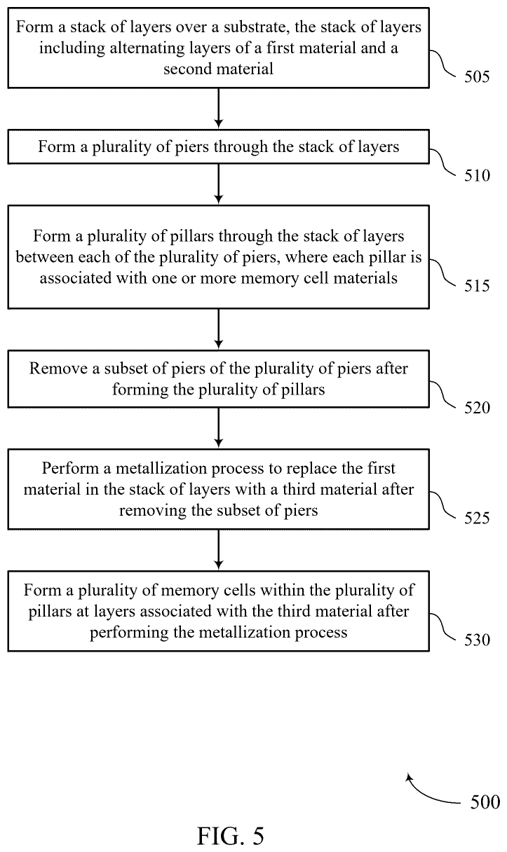

FIG. 5 shows a flowchart illustrating a method or methods 500 that supports memory architectures with replacement gate through piers in accordance with examples as disclosed herein. The operations of method 500 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 505, the method may include forming a stack of layers over a substrate, the stack of layers including alternating layers of a first material and a second material.

At 510, the method may include forming a plurality of piers through the stack of layers.

At 515, the method may include forming a plurality of pillars through the stack of layers between each of the plurality of piers, where each pillar is associated with one or more memory cell materials.

At 520, the method may include removing a subset of piers of the plurality of piers after forming the plurality of pillars.

At 525, the method may include performing a metallization process to replace the first material in the stack of layers with a third material after removing the subset of piers.

At 530, the method may include forming a plurality of memory cells within the plurality of pillars at layers associated with the third material after performing the metallization process.

In some examples, an apparatus (e.g., a manufacturing system) as described herein may perform a method or methods, such as the method 500. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a stack of layers over a substrate, the stack of layers including alternating layers of a first material and a second material; forming a plurality of piers through the stack of layers; forming a plurality of pillars through the stack of layers between each of the plurality of piers, where each pillar is associated with one or more memory cell materials; removing a subset of piers of the plurality of piers after forming the plurality of pillars; performing a metallization process to replace the first material in the stack of layers with a third material after removing the subset of piers; and forming a plurality of memory cells within the plurality of pillars at layers associated with the third material after performing the metallization process.

Aspect 2: The method or apparatus of aspect 1, where performing the metallization process further includes operations, features, circuitry, logic, means, or instructions, or any combination thereof for removing the first material from the stack of layers; depositing a protective liner at least partially around the plurality of piers and the plurality of pillars based at least in part on removing the first material; and depositing the third material in place of the first material based at least in part on depositing the protective liner.

Aspect 3: The method or apparatus of any of aspects 1 through 2, further including operations, features, circuitry, logic, means, or instructions, or any combination thereof for forming, after performing the metallization process and before forming the plurality of memory cells, a second subset of piers positioned at a plurality of first cavities formed by removing the subset of piers.

Aspect 4: The method or apparatus of aspect 3, where forming the second subset of piers includes operations, features, circuitry, logic, means, or instructions, or any combination thereof for depositing a liner material within the plurality of first cavities, where the liner material includes silicon carbonitride; forming a plurality of second cavities through the liner material based at least in part on depositing the liner material; and depositing the second material within the plurality of second cavities.

Aspect 5: The method or apparatus of any of aspects 3 through 4, where forming the subset of piers includes operations, features, circuitry, logic, means, or instructions, or any combination thereof for removing a third subset of piers of the plurality of piers after forming the second subset of piers, where the plurality of piers includes the second subset of piers and the third subset of piers, where forming the plurality of memory cells is based at least in part on removing the third subset of piers.

Aspect 6: The method or apparatus of any of aspects 1 through 5, further including operations, features, circuitry, logic, means, or instructions, or any combination thereof for forming a plurality of first cavities within the stack of layers after forming the plurality of memory cells; depositing a first liner material in the plurality of first cavities; forming a plurality of second cavities in the first liner material; depositing a second liner material in the plurality of second cavities; forming a plurality of third cavities in the second liner material; and depositing a silicon carbide material in the plurality of third cavities.

Aspect 7: The method or apparatus of aspect 6, where the first liner material includes silicon carbide, silicon oxy-carbide, or hafnium silicon oxide and the second liner material includes hafnium oxide.

Aspect 8: The method or apparatus of any of aspects 1 through 7, where forming the plurality of piers further includes operations, features, circuitry, logic, means, or instructions, or any combination thereof for forming a plurality of first cavities through the stack of layers; depositing a first liner material in the plurality of first cavities; forming a plurality of second cavities in the first liner material; depositing a second liner material in the plurality of second cavities; forming a plurality of third cavities in the second liner material; and depositing a polysilicon material in the plurality of third cavities.

Aspect 9: The method or apparatus of aspect 8, where the first liner material includes silicon carbide, silicon oxy-carbide, or hafnium silicon oxide and the second liner material includes silicon carbonitride.

Aspect 10: The method or apparatus of any of aspects 1 through 9, further including operations, features, circuitry, logic, means, or instructions, or any combination thereof for forming a plurality of electrodes at layers associated with the first material after forming the plurality of piers, where the plurality of electrodes are positioned between each of the plurality of piers.

Aspect 11: The method or apparatus of aspect 10, where forming the plurality of electrodes further includes operations, features, circuitry, logic, means, or instructions, or any combination thereof for forming a plurality of first cavities through the stack of layers between each of the plurality of piers, where each first cavity includes a first area at layers associated with the first material and a second area at layers associated with the second material; depositing an electrode material in the first area of each first cavity; forming a plurality of second cavities in the electrode material after depositing the electrode material; and depositing a liner material in the plurality of second cavities, where the liner material includes silicon carbonitride.

Aspect 12: The method or apparatus of any of aspects 1 through 11, where forming the plurality of pillars further includes operations, features, circuitry, logic, means, or instructions, or any combination thereof for forming a plurality of first cavities through the stack of layers; depositing an electrode material in the plurality of first cavities; forming a plurality of second cavities through the electrode material; depositing a barrier material in the plurality of second cavities, where the barrier material includes titanium nitride; forming a plurality of third cavities through the barrier material; and depositing the third material in the plurality of third cavities.

Aspect 13: The method or apparatus of any of aspects 1 through 12, where the first material includes nitride, the second material includes oxide, and the third material includes tungsten.

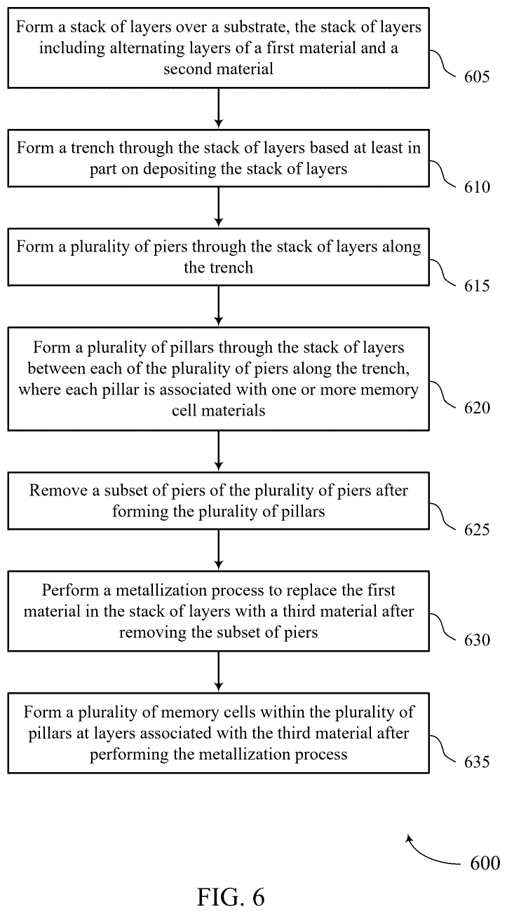

FIG. 6 shows a flowchart illustrating a method 600 that supports memory architectures with replacement gate through piers in accordance with examples as disclosed herein. The operations of method 1000 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include forming a stack of layers over a substrate, the stack of layers including alternating layers of a first material and a second material.

At 610, the method may include forming a trench through the stack of layers based at least in part on depositing the stack of layers.

At 615, the method may include forming a plurality of piers through the stack of layers along the trench.

At 620, the method may include forming a plurality of pillars through the stack of layers between each of the plurality of piers along the trench, where each pillar is associated with one or more memory cell materials.

At 625, the method may include removing a subset of piers of the plurality of piers after forming the plurality of pillars.

At 630, the method may include performing a metallization process to replace the first material in the stack of layers with a third material after removing the subset of piers.

At 635, the method may include forming a plurality of memory cells within the plurality of pillars at layers associated with the third material after performing the metallization process.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 14: A method or apparatus including operations, features, circuitry, logic, means, or instructions, or any combination thereof for forming a stack of layers over a substrate, the stack of layers including alternating layers of a first material and a second material; forming a trench through the stack of layers based at least in part on depositing the stack of layers; forming a plurality of piers through the stack of layers along the trench; forming a plurality of pillars through the stack of layers between each of the plurality of piers along the trench, where each pillar is associated with one or more memory cell materials; removing a subset of piers of the plurality of piers after forming the plurality of pillars; performing a metallization process to replace the first material in the stack of layers with a third material after removing the subset of piers; and forming a plurality of memory cells within the plurality of pillars at layers associated with the third material after performing the metallization process.

Aspect 15: The method or apparatus of aspect 14, where forming the trench further includes operations, features, circuitry, logic, means, or instructions, or any combination thereof for etching an interleaving pattern through the stack of layers to form an interleaved pair of comb structures of the stack of layers and filling the interleaving pattern with a silicon oxide material.

Aspect 16: The method or apparatus of any of aspects 14 through 15, where performing the metallization process further includes operations, features, circuitry, logic, means, or instructions, or any combination thereof for removing the first material from the stack of layers; depositing a barrier material at least partially around the plurality of piers and the plurality of pillars based at least in part on removing the first material; and depositing the third material in place of the first material based at least in part on depositing the barrier material.

Aspect 17: The method or apparatus of any of aspects 14 through 16, further including operations, features, circuitry, logic, means, or instructions, or any combination thereof for forming, after performing the metallization process and before forming the plurality of memory cells, a second subset of piers positioned at a plurality of first cavities formed by removing the subset of piers.

Aspect 18: The method or apparatus of aspect 17, where forming the second subset of piers includes operations, features, circuitry, logic, means, or instructions, or any combination thereof for depositing a liner material within the plurality of first cavities, where the liner material includes silicon carbonitride; forming a plurality of second cavities through the liner material based at least in part on depositing the liner material; and depositing the second material within the plurality of second cavities.

Aspect 19: The method or apparatus of any of aspects 17 through 18, where forming the subset of piers includes operations, features, circuitry, logic, means, or instructions, or any combination thereof for removing a third subset of piers of the plurality of piers after forming the second subset of piers, where the plurality of piers includes the second subset of piers and the third subset of piers, where forming the plurality of memory cells is based at least in part on removing the third subset of piers.

Aspect 20: The method or apparatus of any of aspects 14 through 19, further including operations, features, circuitry, logic, means, or instructions, or any combination thereof for forming a plurality of first cavities within the stack of layers after forming the plurality of memory cells; depositing a first liner material in the plurality of first cavities, the first liner material including silicon carbide, silicon oxy-carbide, or hafnium silicon oxide; forming a plurality of second cavities in the first liner material; depositing a second liner material in the plurality of second cavities, the second liner material including hafnium oxide; forming a plurality of third cavities in the second liner material; and depositing a silicon carbide material in the plurality of third cavities.

Aspect 21: The method or apparatus of any of aspects 14 through 20, where forming the plurality of piers further includes operations, features, circuitry, logic, means, or instructions, or any combination thereof for forming a plurality of first cavities through the stack of layers; depositing a first liner material in the plurality of first cavities, the first liner material including silicon carbide, silicon oxy-carbide, or hafnium silicon oxide; forming a plurality of second cavities in the first liner material; depositing a second liner material in the plurality of second cavities, the second liner material including silicon carbonitride; forming a plurality of third cavities in the second liner material; and depositing a polysilicon material in the plurality of third cavities.

Aspect 22: The method or apparatus of any of aspects 14 through 21, further including operations, features, circuitry, logic, means, or instructions, or any combination thereof for forming a plurality of electrodes at layers associated with the first material after forming the plurality of piers, where the plurality of electrodes are positioned between each of the plurality of piers, and where forming the plurality of electrodes includes; forming a plurality of first cavities through the stack of layers between each of the plurality of piers, where each first cavity includes a first area at layers associated with the first material and a second area at layers associated with the second material; depositing an electrode material in the first area of each first cavity; forming a plurality of second cavities in the electrode material after depositing the electrode material; and depositing a liner material in the plurality of second cavities, where the liner material includes silicon carbonitride.

It should be noted that the methods described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 23: An apparatus, including: a substrate; a stack of layers including alternating layers of a first material and a second material; a plurality of first piers extending through the stack of layers; a plurality of second piers extending through the stack of layers, the plurality of second piers alternating with the plurality of first piers along a direction; a plurality of pillars extending through the stack of layers, where each pillar is positioned between a first pier of the plurality of first piers and a second pier of the plurality of second piers; a protective liner at least partially surrounding the plurality of pillars and positioned at layers associated with the first material; and a plurality of memory cells contacting the plurality of pillars and a plurality of electrodes, where each memory cell is positioned at layers associated with the first material.

Aspect 24: The apparatus of aspect 23, where the first material is tungsten, the second material includes oxide, and the protective liner including titanium nitride.

Aspect 25: The apparatus of any of aspects 23 through 24, where: each first pier of the plurality of first piers includes the second material and a liner material surrounding the second material; the liner material includes silicon carbonitride; each second pier of the plurality of second piers includes a silicon carbide material, a first liner material surrounding the silicon carbide material, and a second liner material at least partially surrounding the first liner material; and the first liner material includes hafnium oxide and the second liner material includes silicon carbide, silicon oxy-carbide, or hafnium silicon oxide.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals are capable of being communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three-dimensional structure where two dimensions are greater than a third, e.g., a thin-film. Layers or levels may include different elements, components, or materials. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, digital subscriber line (DSL), or wireless technologies such as infrared, radio, and microwave are included in the definition of medium. Disk and disc, as used herein, include CD, laser disc, optical disc, digital versatile disc (DVD), floppy disk and Blu-ray disc where disks usually reproduce data magnetically, while discs reproduce data optically with lasers. Combinations of the above are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method, comprising:
forming a stack of layers over a substrate, the stack of layers comprising alternating layers of a first material and a second material;
forming a plurality of piers through the stack of layers;
forming a plurality of pillars through the stack of layers between each of the plurality of piers, wherein each pillar is associated with one or more memory cell materials;
removing a subset of piers of the plurality of piers after forming the plurality of pillars;
performing a metallization process to replace the first material in the stack of layers with a third material after removing the subset of piers; and
forming a plurality of memory cells within the plurality of pillars at layers associated with the third material after performing the metallization process.

2. The method of claim 1, wherein performing the metallization process further comprises:
removing the first material from the stack of layers;
depositing a protective liner at least partially around the plurality of piers and the plurality of pillars based at least in part on removing the first material; and
depositing the third material in place of the first material based at least in part on depositing the protective liner.

3. The method of claim 1, further comprising:
forming, after performing the metallization process and before forming the plurality of memory cells, a second subset of piers positioned at a plurality of first cavities formed by removing the subset of piers.

4. The method of claim 3, wherein forming the second subset of piers comprises:
depositing a liner material within the plurality of first cavities, wherein the liner material comprises silicon carbonitride;
forming a plurality of second cavities through the liner material based at least in part on depositing the liner material; and
depositing the second material within the plurality of second cavities.

5. The method of claim 3, wherein forming the subset of piers comprises:
removing a third subset of piers of the plurality of piers after forming the second subset of piers, wherein the plurality of piers comprises the second subset of piers and the third subset of piers, wherein forming the plurality of memory cells is based at least in part on removing the third subset of piers.

6. The method of claim 1, further comprising:
forming a plurality of first cavities within the stack of layers after forming the plurality of memory cells;
depositing a first liner material in the plurality of first cavities;
forming a plurality of second cavities in the first liner material;
depositing a second liner material in the plurality of second cavities;
forming a plurality of third cavities in the second liner material; and
depositing a silicon carbide material in the plurality of third cavities.

7. The method of claim 6, wherein
the first liner material comprises silicon carbide, silicon oxy-carbide, or hafnium silicon oxide, and
the second liner material comprises hafnium oxide.

8. The method of claim 1, wherein forming the plurality of piers further comprises:
forming a plurality of first cavities through the stack of layers;
depositing a first liner material in the plurality of first cavities;
forming a plurality of second cavities in the first liner material;
depositing a second liner material in the plurality of second cavities;
forming a plurality of third cavities in the second liner material; and
depositing a polysilicon material in the plurality of third cavities.

9. The method of claim 8, wherein
the first liner material comprises silicon carbide, silicon oxy-carbide, or hafnium silicon oxide, and
the second liner material comprises silicon carbonitride.

10. The method of claim 1, further comprising:
forming a plurality of electrodes at layers associated with the first material after forming the plurality of piers, wherein the plurality of electrodes are positioned between each of the plurality of piers.

11. The method of claim 10, wherein forming the plurality of electrodes further comprises:
forming a plurality of first cavities through the stack of layers between each of the plurality of piers, wherein each first cavity comprises a first area at layers associated with the first material and a second area at layers associated with the second material;
depositing an electrode material in the first area of each first cavity;
forming a plurality of second cavities in the electrode material after depositing the electrode material; and
depositing a liner material in the plurality of second cavities, wherein the liner material comprises silicon carbonitride.

12. The method of claim 1, wherein forming the plurality of pillars further comprises:
forming a plurality of first cavities through the stack of layers;
depositing an electrode material in the plurality of first cavities;
forming a plurality of second cavities through the electrode material;
depositing a barrier material in the plurality of second cavities, wherein the barrier material comprises titanium nitride;
forming a plurality of third cavities through the barrier material; and
depositing the third material in the plurality of third cavities.

13. The method of claim 1, wherein the first material comprises nitride, the second material comprises oxide, and the third material comprises tungsten.

14. A method, comprising:
forming a stack of layers over a substrate, the stack of layers comprising alternating layers of a first material and a second material;
forming a trench through the stack of layers based at least in part on depositing the stack of layers;
forming a plurality of piers through the stack of layers along the trench;
forming a plurality of pillars through the stack of layers between each of the plurality of piers along the trench, wherein each pillar is associated with one or more memory cell materials;
removing a subset of piers of the plurality of piers after forming the plurality of pillars;
performing a metallization process to replace the first material in the stack of layers with a third material after removing the subset of piers; and
forming a plurality of memory cells within the plurality of pillars at layers associated with the third material after performing the metallization process.

15. The method of claim 14, wherein forming the trench further comprises:
etching an interleaving pattern through the stack of layers to form an interleaved pair of comb structures of the stack of layers; and
filling the interleaving pattern with a silicon oxide material.

16. The method of claim 14, wherein performing the metallization process further comprises:
removing the first material from the stack of layers;
depositing a protective liner at least partially around the plurality of piers and the plurality of pillars based at least in part on removing the first material; and
depositing the third material in place of the first material based at least in part on depositing the protective liner.

17. The method of claim 14, further comprising:
forming, after performing the metallization process and before forming the plurality of memory cells, a second subset of piers positioned at a plurality of first cavities formed by removing the subset of piers.

18. The method of claim 17, wherein forming the second subset of piers comprises:
depositing a liner material within the plurality of first cavities, wherein the liner material comprises silicon carbonitride;
forming a plurality of second cavities through the liner material based at least in part on depositing the liner material; and
depositing the second material within the plurality of second cavities.

19. The method of claim 17, wherein forming the subset of piers comprises:
removing a third subset of piers of the plurality of piers after forming the second subset of piers, wherein the plurality of piers comprises the second subset of piers and the third subset of piers, wherein forming the plurality of memory cells is based at least in part on removing the third subset of piers.

20. The method of claim 14, further comprising:
forming a plurality of first cavities within the stack of layers after forming the plurality of memory cells;
depositing a first liner material in the plurality of first cavities, the first liner material comprising silicon carbide, silicon oxy-carbide, or hafnium silicon oxide;
forming a plurality of second cavities in the first liner material;
depositing a second liner material in the plurality of second cavities, the second liner material comprising hafnium oxide;
forming a plurality of third cavities in the second liner material; and
depositing a silicon carbide material in the plurality of third cavities.

21. The method of claim 14, wherein forming the plurality of piers further comprises:
forming a plurality of first cavities through the stack of layers;
depositing a first liner material in the plurality of first cavities, the first liner material comprising silicon carbide, silicon oxy-carbide, or hafnium silicon oxide;
forming a plurality of second cavities in the first liner material;
depositing a second liner material in the plurality of second cavities, the second liner material comprising silicon carbonitride;
forming a plurality of third cavities in the second liner material; and
depositing a polysilicon material in the plurality of third cavities.

22. The method of claim 14, further comprising:
forming a plurality of electrodes at layers associated with the first material after forming the plurality of piers, wherein the plurality of electrodes are positioned between each of the plurality of piers, and wherein forming the plurality of electrodes comprises:
forming a plurality of first cavities through the stack of layers between each of the plurality of piers, wherein each first cavity comprises a first area at layers associated with the first material and a second area at layers associated with the second material;
depositing an electrode material in the first area of each first cavity;
forming a plurality of second cavities in the electrode material after depositing the electrode material; and
depositing a liner material in the plurality of second cavities, wherein the liner material comprises silicon carbonitride.

23. An apparatus, comprising:
a substrate;
a stack of layers comprising alternating layers of a first material and a second material;
a plurality of first piers extending through the stack of layers;
a plurality of second piers extending through the stack of layers, the plurality of second piers alternating with the plurality of first piers along a direction;
a plurality of pillars extending through the stack of layers, wherein each pillar is positioned between a first pier of the plurality of first piers and a second pier of the plurality of second piers;
a protective liner at least partially surrounding the plurality of pillars and positioned at layers associated with the first material; and
a plurality of memory cells contacting the plurality of pillars and a plurality of electrodes, wherein each memory cell is positioned at layers associated with the first material.

24. The apparatus of claim 23, wherein the first material is tungsten, the second material comprises oxide, and the protective liner comprising titanium nitride.

25. The apparatus of claim 23, wherein:
each first pier of the plurality of first piers comprises the second material and a liner material surrounding the second material;
the liner material comprises silicon carbonitride;
each second pier of the plurality of second piers comprises a silicon carbide material, a first liner material surrounding the silicon carbide material, and a second liner material at least partially surrounding the first liner material; and
the first liner material comprises hafnium oxide and the second liner material comprises silicon carbide, silicon oxy-carbide, or hafnium silicon oxide.
